(19) United States
(12) Patent Application Publication
(10) Pub. No.: US 2026/0314304 A1
(43) Pub. Date: Oct. 8, 2026

(54) SUBSTRATE PRODUCTION METHOD AND SUBSTRATE PRODUCTION APPARATUS

(71) Applicant: EBARA CORPORATION, Tokyo (JP)

(72) Inventor: Masayuki SATAKE, Tokyo (JP)

(21) Appl. No.: 18/880,633

(22) PCT Filed: Jun. 15, 2023
(86) PCT No.: PCT/JP2023/022221

§ 371 Date: Jan. 7, 2026

(30) Foreign Application Priority Data
Jul. 13, 2022 (JP) 2022-112208

(51) Int. Cl. H10P 72/00; H10P 10/00; H10P 52/00

(52) U.S. Cl. CPC H10P 72/0448; H10P 10/12; H10P 52/00; H10P 72/0402; H10P 72/0428

(57) ABSTRACT

The application relates to a substrate manufacturing method and a substrate manufacturing apparatus. The substrate manufacturing method includes a step of applying a filler to a gap between a bevel portion of a first substrate and a bevel portion of a second substrate, and a step of removing air bubbles from the filler applied to the gap.

### TECHNICAL FIELD

The present invention relates to a substrate manufacturing method and a substrate manufacturing apparatus.

### BACKGROUND ART

In three-dimensional packaging technology for laminating and integrating substrates, device surfaces of the substrates are bonded together, and then a non-device surface of one of the substrates is ground. The substrate has a rounded or chamfered shape (beveled portion) on a peripheral portion of the substrate.

Therefore, when a bevel portion becomes thin due to grinding, a sharp edge portion (knife edge portion) is formed, which may result in defects such as cracks and chips. Therefore, in a bevel fill technology, a gap between the bevel portions in a laminated substrate is filled with a filler, which supports the knife edge portion and prevents an occurrence of defects.

### CITATION LIST

### Patent Literature

Patent document 1: Japanese laid-open patent publication No. 2022-38834

### SUMMARY OF INVENTION

### Technical Problem

However, if air bubbles are mixed in the filler applied to the gap between the beveled portions, the air bubbles (i.e., cavities) inside the filler may cause defects in the substrate. More specifically, when a grinding load is applied to the knife edge portion, the filler may not be able to fully support the knife edge portion in the cavity portion, and as a result, defects such as cracks and chips may occur in the substrate.

Therefore, the present invention provides a substrate manufacturing method and substrate manufacturing apparatus that are capable of preventing defects from occurring in a substrate due to air bubbles mixed in a filler.

### Solution to Problem

In an embodiment, there is provided a substrate manufacturing method for manufacturing a laminated substrate formed by bonding a first substrate and a second substrate, comprising: a step of applying a filler to a gap between a bevel portion of the first substrate and a bevel portion of the second substrate; and a step of removing air bubbles from the filler applied to the gap.

In an embodiment, the step of removing the air bubbles comprises a step of vibrating the laminated substrate through a substrate holding device configured to hold the laminated substrate.

In an embodiment, the step of removing the air bubbles comprises a step of ejecting a pressurized fluid onto the filler applied to the gap.

In an embodiment, comprising a step of removing the air bubbles from the filler before the filler is applied to the gap.

In an embodiment, comprising a step of curing the filler applied to the gap after the step of removing the air bubbles.

In an embodiment, comprising a step of grinding the laminated substrate.

In an embodiment, there is provided a substrate manufacturing apparatus for manufacturing a laminated substrate formed by bonding a first substrate and a second substrate, comprising: a coating device configured to apply a filler to a gap between a bevel portion of the first substrate and a bevel portion of the second substrate; and an air bubble removal device configured to remove air bubbles from the filler applied to the gap.

In an embodiment, the air bubble removal device comprises a vibration device configured to vibrate the laminated substrate through a substrate holding device configured to hold the laminated substrate.

In an embodiment, the air bubble removal device comprises a fluid ejection device configured to eject a pressurized fluid into the filler applied to the gap.

In an embodiment, the coating device comprises an injection nozzle configured to inject a pressurized fluid onto the filler supplied to a supply nozzle configured to supply the filler toward the gap.

In an embodiment, comprising a curing device configured to cure the filler applied to the gap.

In an embodiment, the curing device is disposed downstream of a fluid ejection device configured to eject a pressurized fluid onto the filler applied to the gap in a rotation direction of the substrate.

### Advantageous Effects of Invention

By removing the air bubbles from the filler applied to the gap of the laminated wafer, it is possible to prevent defects such as cracks and chips in the substrate caused by the air bubbles mixed in the filler.

### BRIEF DESCRIPTION OF DRAWINGS

FIG. 1A is an enlarged cross-sectional view showing a peripheral portion of a wafer, which is an example of a substrate;

FIG. 1B is an enlarged cross-sectional view showing a peripheral portion of a wafer, which is an example of a substrate;

FIG. 2A is a schematic view showing an example of a laminated wafer obtained by bonding two wafers;

FIG. 2B is a schematic view showing the laminated wafer after the second wafer shown in FIG. 2A has been ground (thinned);

FIG. 3 is a view showing an embodiment of a substrate manufacturing apparatus;

FIG. 4A is a view showing a state in which a filler is applied to the laminated wafer;

FIG. 4B is a view showing a size of the filler applied to the laminated wafer;

FIG. 5 is a view showing another embodiment of the air bubble removal device;

FIG. 6A is a view showing a state in which the pressurized fluid is ejected into a gap of the laminated wafer;

FIG. 6B is a view showing a state in which the pressurized fluid is ejected into the gap of the laminated wafer;

FIG. 7 is a view showing another embodiment of the coating device;

FIG. 8 is a view showing a curing device that cures the filler applied to the gap of the laminated wafer; and

FIG. 9 is a view showing a combination of the fluid ejection device as an air bubble removal device and a curing device.

### DESCRIPTION OF EMBODIMENTS

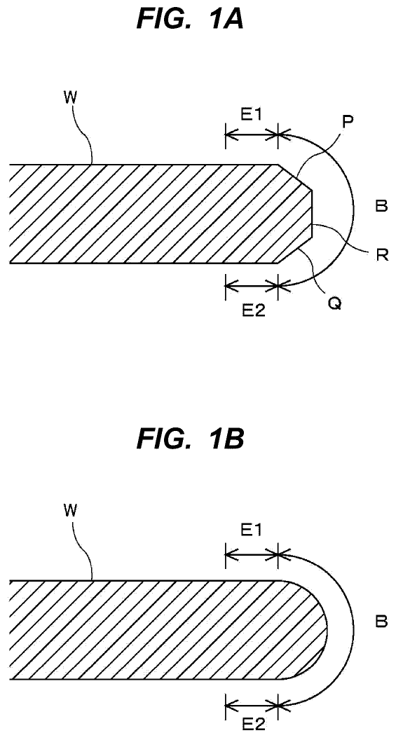

FIGS. 1A and 1B are enlarged cross-sectional views showing a peripheral portion of a wafer, which is an example of a substrate. More specifically, FIG. 1A is a cross-sectional view of a so-called straight type wafer, and FIG. 1B is a cross-sectional view of a so-called round type wafer. In the wafer W of FIG. 1A, a bevel portion is an outermost peripheral surface (indicated by the symbol B) of the wafer W, which is composed of an upper inclined portion (upper bevel portion) P, a lower inclined portion (lower bevel portion) Q, and a side portion (apex) R.

In the wafer W of FIG. 1B, the bevel portion is a portion (indicated by the symbol B) having a curved cross section that constitutes the outermost peripheral surface of the wafer W. A top edge portion E1 is a flat portion that is located radially inward from the bevel portion B and radially outward from a region D where devices are formed. The top edge portion E1 may also include a region where devices are formed. A bottom edge portion E2 is a flat portion that is located on an opposite side to the top edge portion E1 and radially inward from the bevel portion B. The top edge portion E1 and the bottom edge portion E2 are sometimes collectively referred to as near edge portions.

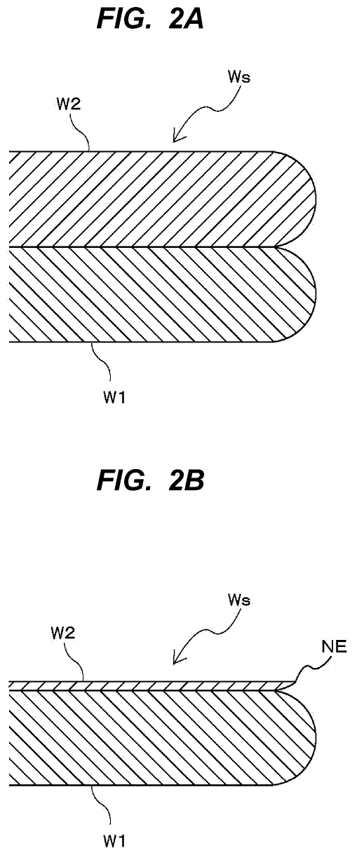

FIG. 2A is a schematic view showing an example of a laminated wafer obtained by bonding two wafers, and FIG. 2B is a schematic view showing the laminated wafer after the second wafer shown in FIG. 2A has been ground (thinned). A laminated wafer Ws shown in FIG. 2A is manufactured by bonding a rounded first wafer W1 and a rounded second wafer W2 shown in FIG. 1B.

As shown in FIG. 2B, when the second wafer W2 is thinned, a knife edge portion NE is formed on the peripheral portion of the second wafer W2. This knife edge portion NE is easily chipped by physical contact, which may result in defects such as cracks and chips in the laminated wafer Ws. Therefore, the knife edge portion NE is effectively protected by applying a filler between the first wafer W1 and the second wafer W2 of the laminated wafer Ws and curing the filler.

However, if air bubbles are mixed in the filler, there is a risk of defects such as cracks and chips occurring in the knife edge portion NE. Therefore, hereinafter, a substrate manufacturing apparatus capable of preventing defects from occurring in the laminated wafer Ws due to air bubbles mixed in the filler will be described with reference to the drawings.

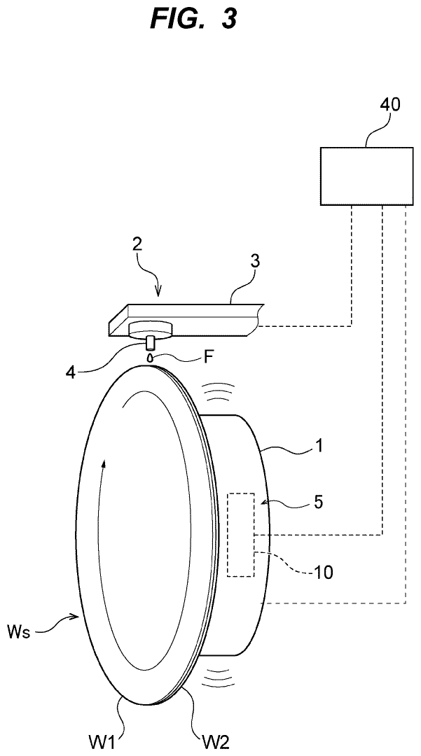

FIG. 3 is a view showing an embodiment of a substrate manufacturing apparatus. The substrate manufacturing apparatus is an apparatus for manufacturing (i.e., processing) the laminated wafer Ws formed by bonding the first wafer W1 and the second wafer W2 together. Therefore, the substrate manufacturing apparatus may be called a substrate processing apparatus.

The substrate manufacturing apparatus includes a substrate holding device 1 that holds the laminated wafer Ws, a coating device 2 that applies a filler F to the gap between the bevel portion B of the first wafer W1 and the bevel portion B of the second wafer W2 (i.e., the gap of the laminated wafer Ws), and an air bubble removal device 5 that removes the air bubbles from the filler F applied to the gap of the laminated wafer Ws.

In the embodiment shown in FIG. 3, the substrate holding device 1 is a device that rotates the laminated wafer Ws while holding the laminated wafer Ws in a vertical direction by vacuum suction, but the substrate holding device 1 may also be configured to rotate the laminated wafer Ws while holding them in a horizontal direction.

In one embodiment, the substrate holding device 1 may be a combination of a plurality of holding rollers. With such a combination, the substrate holding device 1 can rotate the laminated wafer Ws while holding the laminated wafer Ws in the vertical direction.

The coating device 2 is disposed above the laminated wafer Ws held in a vertical direction. More specifically, the laminated wafer Ws is held with its plane surface perpendicular to a horizontal plane. In other words, the laminated wafer Ws is held in an upright position. The coating device 2 includes a supply nozzle 4 that supplies the filler F toward the gap of the laminated wafer Ws, and a support arm 3 that supports the supply nozzle 4.

In the embodiment shown in FIG. 3, the air bubble removal device 5 includes a vibration device 10 that vibrates the laminated wafer Ws through the substrate holding device 1. The vibration device 10 is, for example, an ultrasonic vibrator. The vibration device 10 vibrates the laminated wafer Ws, thereby vibrating the filler F applied in the gap of the laminated wafer Ws through the laminated wafer Ws.

The vibration device 10 vibrates the air bubbles mixed in the filler F, causing adjacent the air bubbles to bond together. The bonded air bubbles become larger air bubbles and are discharged (degassed) to an outside of the filler F. In this manner, the air bubble removal device 5 (more specifically, the vibration device 10) can remove the air bubbles from the filler F applied to the gaps of the laminated wafer Ws.

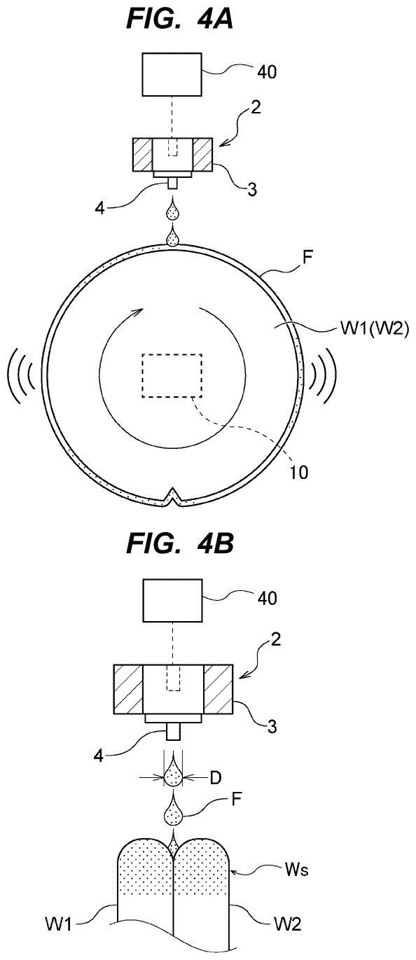

FIG. 4A is a view showing a state in which the filler is applied to the laminated wafer, and FIG. 4B is a view showing a size of the filler applied to the laminated wafer. The substrate manufacturing apparatus includes a control device 40 that controls operations of the substrate holding device 1, the coating device 2, and the air bubble removal device 5. The control device 40 operates the substrate holding device 1 and the coating device 2 to rotate the laminated wafer Ws and to supply the filler F from above the laminated wafer Ws through the supply nozzle 4.

By supplying the filler F while rotating the laminated wafer Ws, the gap of the laminated wafer Ws is filled with the filler F over an entire circumference of the laminated wafer Ws (see FIG. 4A). In this embodiment, as shown in FIG. 4B, a size D (i.e., line width) of the filler F applied from the supply nozzle 4 is 0.2 to 0.3 mm, which corresponds to a size of the gap of the laminated wafer Ws.

The control device 40 operates the air bubble removal device 5 (more specifically, the vibration device 10) to vibrate the laminated wafer Ws when the filler F is applied to the gap of the laminated wafer Ws, thereby removing the air bubbles from the filler F applied to the gap of the laminated wafer Ws. The control device 40 continues vibration by the vibration device 10 until the air bubbles are removed from the filler F. After the filler F is applied to the gap of the laminated wafer Ws, a grinding process is performed to grind (thin) the first wafer W1 or the second wafer W2.

According to the embodiment, the air bubble removal device 5 can remove the air bubbles from the filler F applied to the gap of the laminated wafer Ws. Therefore, the substrate manufacturing apparatus can prevent defects such as cracks and chips from occurring in the knife edge portion NE due to the air bubbles mixed in the filler F.

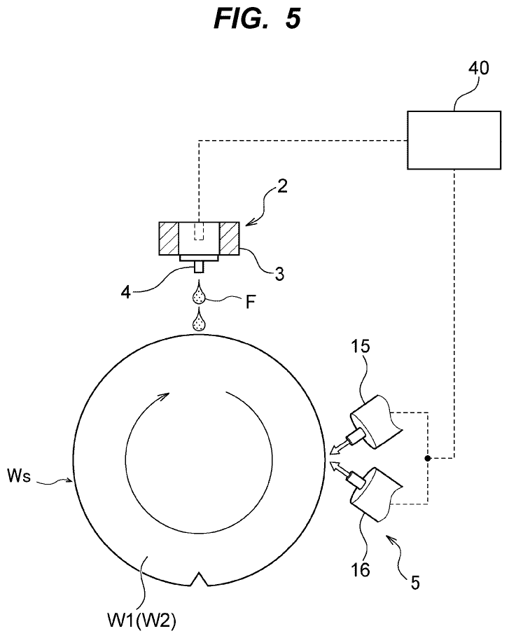

FIG. 5 is a view showing another embodiment of the air bubble removal device. As shown in FIG. 5, the air bubble removal device 5 includes fluid ejection devices 15 and 16 that eject a pressurized fluid into the filler F applied to the gap of the laminated wafer Ws. The pressurized fluid is a fluid to which kinetic energy has been imparted. In this embodiment, the pressurized fluid refers to a gas (e.g., nitrogen gas) pressurized to a pressure required to remove the air bubbles from the filler F.

As shown in FIG. 5, the fluid ejection devices 15 and 16 are disposed adjacent to each other in the vertical direction and are configured to locally eject the pressurized fluid onto the filler F on the gap of the laminated wafer Ws. In one embodiment, the air bubble removal device 5 may include at least one of the fluid ejection devices 15 and 16.

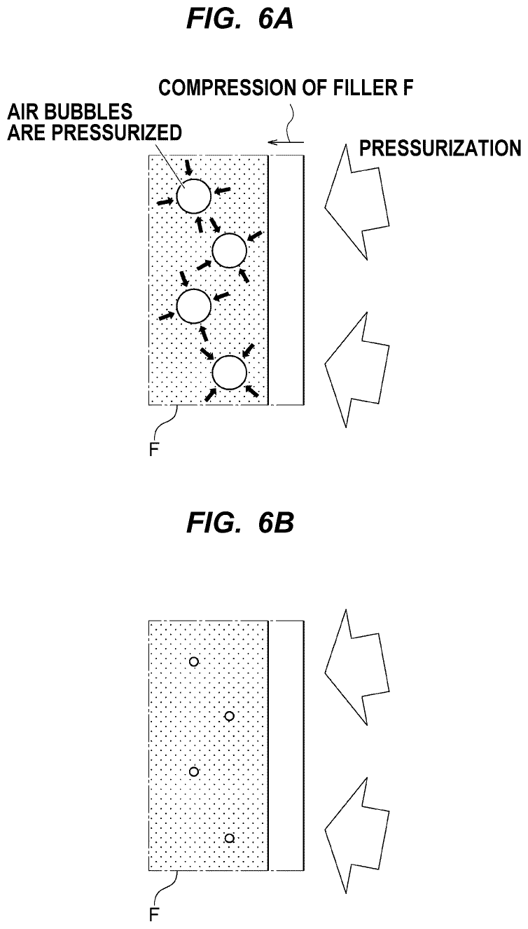

FIGS. 6A and 6B are views showing a state in which the pressurized fluid is ejected into the gap of the laminated wafer. The control device 40 is electrically connected to each of the fluid ejection devices 15 and 16, and can independently control each of the fluid ejection devices 15 and 16. As shown in FIG. 6A, the pressurized fluid is ejected locally into the filler F on the gap between the laminated wafer Ws, whereby the filler F is compressed.

As shown in FIG. 6B, the air bubbles mixed in the filler F are compressed together with the filler F, and eventually become small enough that they do not adversely affect the knife edge portion NE. The size of the air bubbles reduced by the ejection of the pressurized fluid does not return to their original size. In this manner, the air bubble removal device 5 can remove the air bubbles from the filler F applied to the gap of the laminated wafer Ws.

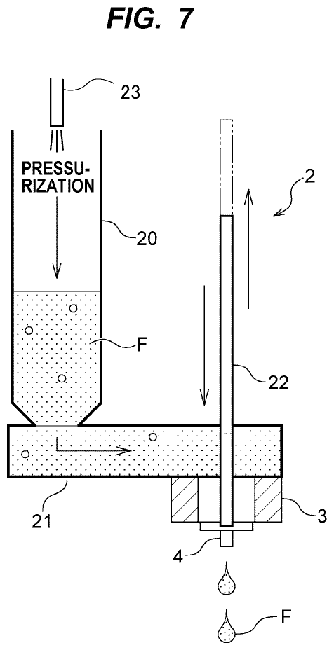

FIG. 7 is a view showing another embodiment of the coating device. As shown in FIG. 7, the coating device 2 may include a syringe body 20 filled with the filler F, an introduction portion 21 that introduces the filler F in the syringe body 20 to the supply nozzle 4 through the support arm 3, a rod 22 that pushes the filler F in the introduction portion 21 to the supply nozzle 4, and an injection nozzle 23 that ejects a pressurized fluid (e.g., nitrogen gas) into the filler in the syringe body 20.

There may be cases where the air bubbles have already been mixed into the filler F in the syringe body 20. Therefore, in the embodiment shown in FIG. 7, the injection nozzle 23 is configured to inject the pressurized fluid into the filler F supplied to the supply nozzle 4 (i.e., the filler F in the syringe body 20) to remove the air bubbles from the filler F before it is applied to the gap of the laminated wafer Ws.

The control device 40 is configured to be able to control an operation of the injection nozzle 23. More specifically, the control device 40 is electrically connected to a fluid supply source (not shown) that supplies the pressurized fluid through the injection nozzle 23. By injecting the pressurized fluid from the injection nozzle 23, the air bubbles mixed in the filler F inside the syringe body 20 are compressed together with the filler F, and eventually become small enough that they do not adversely affect the knife edge portion NE (see FIGS. 6A and 6B).

The control device 40 is configured to be able to control an operation of the rod 22. More specifically, the control device 40 is electrically connected to a vertical movement device (not shown) that moves the rod 22 up and down. An example of the rod 22 is a piston rod.

With the air bubble removed from the filler F in the syringe body 20, the rod 22 is moved up and down, whereby the filler F in the introduction portion 21 is supplied through the supply nozzle 4 toward the gap of the laminated wafer Ws.

According to this embodiment, the air bubble can be removed from the filler F before it is applied to the gap of the laminated wafer Ws, thereby preventing defects such as cracks and chips from occurring in the knife edge portion NE due to the air bubbles mixed in the filler F.

The embodiment shown in FIG. 3, the embodiment shown in FIG. 5, and the embodiment shown in FIG. 7 can be appropriately combined as necessary. By such a combination, the air bubble mixed in the filler F can be more effectively removed. Note that the substrate manufacturing apparatus may include only the configuration according to the embodiment shown in FIG. 7, instead of including the air bubble removal device 5 (see FIGS. 3 and 5).

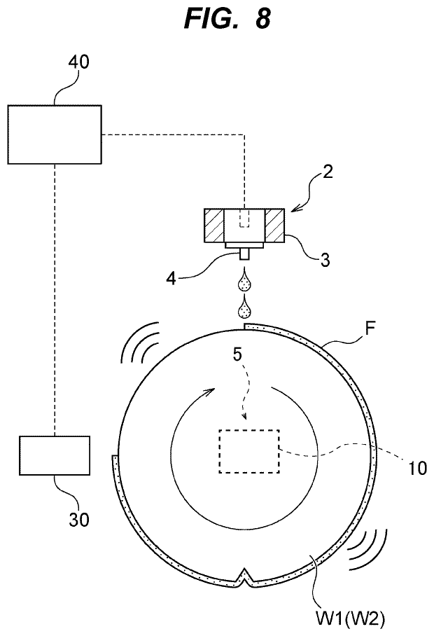

FIG. 8 is a view showing a curing device that cures the filler applied to the gap of the laminated wafer. As shown in FIG. 8, the substrate manufacturing apparatus may include a curing device 30 that cures the filler F applied to the gap of the laminated wafer Ws. The control device 40 is electrically connected to the curing device 30 and can control an operation of the curing device 30.

In one embodiment, when a filler F that is cured by irradiation with ultraviolet rays is used, the curing device 30 may be an ultraviolet irradiation device that irradiates ultraviolet rays to the filler F to cure the filler F. In one embodiment, when a filler F that is cured by moisture is used, the curing device 30 may be a mist supplying device that supplies mist to the filler F to cure the filler F. In one embodiment, the curing device 30 may be a heater that supplies high-temperature gas (i.e., a temperature required to cure the filler F) to the filler F to heat the filler F. The temperature required to cure the filler Fis, in other words, the curing temperature.

As shown in FIG. 8, the substrate manufacturing apparatus may include the coating device 2, the air bubble removal device 5 (more specifically, the vibration device 10), and the curing device 30. With this configuration, the application of the filler F, the removal of the air bubbles, and the curing of the filler F can be performed in a short time, and as a result, a process time for the laminated wafer Ws can be shortened. Although not shown, the substrate manufacturing apparatus may further include the injection nozzle 23 (see FIG. 7) that injects the pressurized fluid into the filler F supplied to the supply nozzle 4.

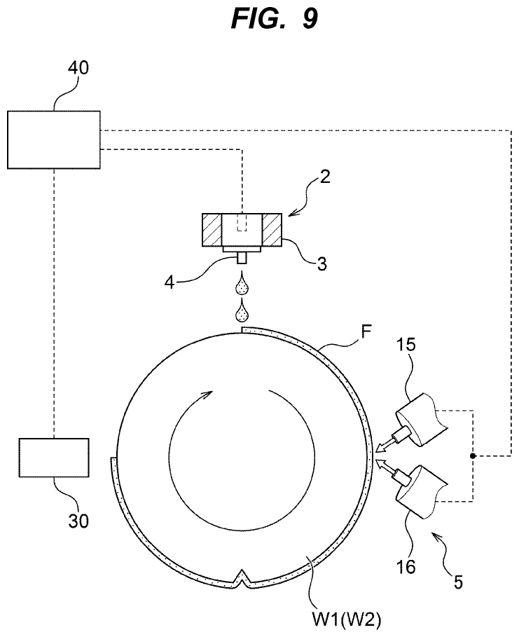

FIG. 9 is a view showing a combination of the fluid ejection device as an air bubble removal device and a curing device. As shown in FIG. 9, the substrate manufacturing apparatus may include the fluid ejection devices 15 and 16 and the curing device 30. Although not shown, the substrate manufacturing apparatus may further include the injection nozzle 23 (see FIG. 7) that injects the pressurized fluid into the filler F supplied to the supply nozzle 4.

In the embodiment shown in FIG. 9, the curing device 30 is disposed downstream of the fluid ejection devices 15 and 16 in a rotation direction of the laminated wafer Ws. In other words, the fluid ejection devices 15 and 16 are disposed between the supply nozzle 4 and the curing device 30 in the rotation direction of the laminated wafer Ws. With this arrangement, the filler F supplied from the supply nozzle 4 is quickly cured after the air bubbles inside the filler F are removed. As a result, the process time of the laminated wafer Ws can be shortened. A grinding process for grinding (thinning) the first wafer W1 or the second wafer W2 is performed after the filler F is cured.

In one embodiment, at least one of the fluid ejection devices 15 and 16 may have the same function as the curing device 30. For example, the fluid ejection device 16 arranged downstream of the fluid ejection device 15 in the rotation direction of the laminated wafer Ws may be configured to eject a heated fluid. With this configuration, the air bubbles in the filler F supplied from the supply nozzle 4 are removed by the fluid ejection device 15, and the filler F is then quickly cured. Although not shown, the air bubble removal device 5 may include not only the fluid ejection devices 15 and 16 but also the vibration device 10.

The above embodiments are described for the purpose of practicing the present invention by a person with ordinary skill in the art to which the invention pertains. Although preferred embodiments have been described in detail above, it should be understood that the present invention is not limited to the illustrated embodiments, but many changes and modifications can be made therein without departing from the appended claims.

### INDUSTRIAL APPLICABILITY

The present invention is applicable to a substrate manufacturing method and a substrate manufacturing apparatus.

### REFERENCE SIGNS LIST

1 substrate holding device
2 coating device
3 support arm
4 supply nozzle
5 air bubble removal device
10 vibration device
15,16 fluid ejection device
20 syringe body
21 introduction portion
22 rod
23 injection nozzle
30 curing device
40 control device

1. A substrate manufacturing method for manufacturing a laminated substrate formed by bonding a first substrate and a second substrate, comprising:
a step of applying a filler to a gap between a bevel portion of the first substrate and a bevel portion of the second substrate; and
a step of removing air bubbles from the filler applied to the gap.

2. The substrate manufacturing method according to claim 1, wherein the step of removing the air bubbles comprises a step of vibrating the laminated substrate through a substrate holding device configured to hold the laminated substrate.

3. The substrate manufacturing method according to claim 1, wherein the step of removing the air bubbles comprises a step of ejecting a pressurized fluid onto the filler applied to the gap.

4. The substrate manufacturing method according to claim 1, comprising a step of removing the air bubbles from the filler before the filler is applied to the gap.

5. The substrate manufacturing method according to claim 1, comprising a step of curing the filler applied to the gap after the step of removing the air bubbles.

6. The substrate manufacturing method according to claim 1, comprising a step of grinding the laminated substrate.

7. A substrate manufacturing apparatus for manufacturing a laminated substrate formed by bonding a first substrate and a second substrate, comprising:
a coating device configured to apply a filler to a gap between a bevel portion of the first substrate and a bevel portion of the second substrate; and
an air bubble removal device configured to remove air bubbles from the filler applied to the gap.

8. The substrate manufacturing apparatus according to claim 7, wherein the air bubble removal device comprises a vibration device configured to vibrate the laminated substrate through a substrate holding device configured to hold the laminated substrate.

9. The substrate manufacturing apparatus according to claim 7, wherein the air bubble removal device comprises a fluid ejection device configured to eject a pressurized fluid into the filler applied to the gap.

10. The substrate manufacturing apparatus according to claim 7, wherein the coating device comprises an injection nozzle configured to inject a pressurized fluid onto the filler supplied to a supply nozzle configured to supply the filler toward the gap.

11. The substrate manufacturing apparatus according to claim 7, comprising a curing device configured to cure the filler applied to the gap.

12. The substrate manufacturing apparatus according to claim 11, wherein the curing device is disposed downstream of a fluid ejection device configured to eject a pressurized fluid onto the filler applied to the gap in a rotation direction of the substrate.
